(19) United States
(12) Patent Application Publication
(10) Pub. No.: US 2007/0229860 A1
(43) Pub. Date: Oct. 4, 2007

(54) Print shop management method and apparatus for printing mixed color and black and white documents

(75) Inventors: Shigenori Matsubara, Irvine, CA (US); Toshiro Fujimori, Laguna Beach, CA (US); Rakesh Pandit, Irvine, CA (US); Geoff W. Harmon, Mission Viejo, CA (US)

Correspondence Address: YING CHEN;Chen Yoshimura LLP, 255 S. GRAND AVE., # 215, LOS ANGELES, CA, 90012, US

(73) Assignee: Konica Minolta Systems Laboratory, Inc.

(21) Appl. No.: 11/395,583

(22) Filed: Mar. 31, 2006

(51) Int. Cl. G03F 3/08

(52) U.S. Cl. 358/1.9; 358/518

(57) ABSTRACT

A method is described for managing a print shop system in which a plurality of printers are connected to and managed by a server. When a document to be printed contains both color pages and black and white pages, the server makes a determination as to whether to submit the entire print job to a color printer, or to split the print job into two sub-jobs by submitting the color pages to a color printer and the black and white pages to a black and white printer. The server preferably makes the decision based on a cost calculation so as to minimize the total cost of printing the entire job, but can also made the decision based on some other considerations.

### BACKGROUND OF THE INVENTION

1. Field of the Invention

This invention relates to a method and apparatus for managing a print shop system in which a plurality of printers are connected to and managed by a server. In particular, it relates to a method and apparatus of managing print jobs and printers in a print shop for printing documents that contain both color and black and white pages.

2. Description of Related Art

A professional print shop typically has a plurality of printers connected to a server by a network, where the server controls the printing of customer jobs on one or more printers. The printers in a print shop typically have different characteristics and capabilities. In particular, a print shop typically has both black and white printers and color printers. A conventional practice is to print documents containing only black and white pages (including gray level images) using black and white printers, and to print documents containing color pages using color printers. Printing with a color printer is typically more costly than printing with a black and white printer.

### SUMMARY OF THE INVENTION

Many documents to be printed contain both color and black and white pages. Some documents predominantly consist of black and white pages with a relatively small number of color pages. To print such documents entirely on a color printer would result in unnecessarily high cost of printing.

Accordingly, the present invention is directed to a method of managing print jobs that contain both black and white and color pages.

An object of the present invention is to reduce the cost of printing when a document contains mixed color and black and white pages.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other objects, as embodied and broadly described, the present invention provides a method for managing a print shop system, the print shop system including a plurality of categories of printers having different color capabilities, the method being implemented on a server connected to the printers, the method including: (a) obtaining a print request and a source document to be printed; (b) analyzing the source document according to definitions of a plurality of color categories that correspond to the color capabilities of the categories of printers to determine which color category each page of the document belongs; (c) determining whether to print the source document on a single category of printers or to print the source document on two or more categories of printers based on the analysis of step (b) and pre-defined criteria; and (d) submitting print requests to one or more categories of printers based on the determination of step (c).

In another aspect, the present invention provides a computer program product that causes a data processing apparatus to perform the above method.

It is to be understood that both the foregoing general description and the following detailed description are exemplary and explanatory and are intended to provide further explanation of the invention as claimed.

### BRIEF DESCRIPTION OF THE DRAWINGS

FIG. 1 is a flow chart illustrating a method for managing print jobs according to an embodiment of the present invention.

FIG. 2 schematically illustrates a print shop system having a plurality of printers connected to a server via a network in which methods according to embodiments of the present invention may be implemented.

### DETAILED DESCRIPTION OF THE PREFERRED EMBODIMENTS

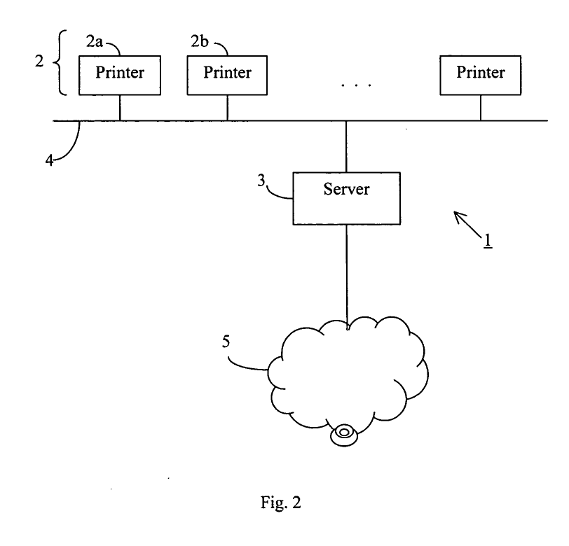

FIG. 2 schematically shows a print shop system 1 having a plurality of printers 2a, 2b, connected to a server (or any suitable data processing apparatus) 3 via a network 4. One or more user terminals (not shown) are also connected to the server to enable print shop operators to interact with the server and the rest of the system. The server 3 is preferably also connected to an external network 5 such as the Internet for receiving print jobs (i.e. print requests from customers and documents to be printed). The server 3, under control of print shop management software, receives print jobs from customers and submits print commands and data to be printed to one or more printers 2. The print shop management software may make various management decisions, such as which printer(s) to use for a print job, either automatically or under various degree of control of an operator.

When a document to be printed (herein after referred to as the source document) is a mixed color document, i.e. one that contains both color pages and black and white pages, the server 3 makes a determination as to whether to submit the entire print job (i.e. all pages of the source document) to a color printer(s), or to split the print job into two sub-jobs by submitting the color pages to a color printer(s) and the black and white pages to a black and white printer(s). According to one embodiment of the present invention, the server makes such a decision based on a cost calculation so as to minimize the total cost of printing the entire job. Generally speaking, if the number of black and white pages in the source document is relatively large, it tends to be more cost-effective to split the print job, whereas if the number of black and white pages is relatively small, it tends to be more cost-effective to print the entire job on a color printer.

When a print job is split into two sub-jobs and printed on a color printer and a black and white printer separately, a job ticket and the source document must be processed to separate the color and black and white pages in the document so that they can be submitted to the different printers. A job ticket, which is associated with the source document, specifies various parameters governs the printing of the document, such as the number of copies, orientation, input tray, output tray, finishing instructions (staple, hole punch, etc.), etc. A commonly owned, co-pending U.S. patent application entitled “Method for Printing Mixed Color and Black and White Documents” (Attorney docket 75675.B084), which is incorporated by reference herein in its entirety, describes exemplary methods for splitting a job ticket into two sub-job tickets, one for color printing and one for black and white printing. The two job tickets are submitted to the color and the black and white printers, respectively. The output pages from the color printer and the black and white printer must then be merged together according to the original page order of the source document to produce the printed document. Merging may be accomplished by first printing one sub-job on one printer, transporting the printed pages to a paper inserter unit of the other printer, then printing the other sub-job using the other printer. The paper inserter unit is a feeder of a printer that feeds the paper in it to the output tray of the printer, without printing on them, in a programmed order concurrently with the printing of another document by the printer. As a result, the pages in the paper inserter unit are merged with the concurrently printed pages according to the programmed order. The first printed sub-job may be either the color sub-job or the black and white sub-job, preferably depending on which has a smaller number of pages because they will take less time to insert during merging, or depending on which printer has the finishing capabilities required by the print job (such as stapling, hole punching, folding, etc.).

An embodiment of the present invention provides a method for determining whether a mixed job should be printed entirely on a color printer or split into a color and a black and white sub-job based on a cost consideration. First, the following parameters are defined:
C: the number of color pages in the source document;
B: the number of black and white pages in the source document;
N: the number of copies of the document to be made;
Pc: the per page cost of printing color pages;
Pb: the per page cost of printing black and white pages; and
E: the cost (effort) of performing split printing.
   The last item, the cost of performing split printing (a job split), includes the cost of the effort to split a job ticket into two sub-job tickets (which is performed by the server, and hence the marginal cost may be negligible), the effort of transporting the output of the first printed sub-job from the first printer to the paper inserter unit of the second printer, the potential cost of recovering from a paper jam or other problems during merging, etc. An appropriate measure of this effort may depend on the cost of labor, etc.

Using these parameters, the cost of printing the entire source document on a color printer is:
Cc=(C+B)*Pc*N
and the cost of splitting the print job and printing only the color pages on a color printer is:
Cs=[(C*Pc)+(B*Pb)]*N+E.
Note that the cost of performing a job split E is incurred once regardless of the number of copies made, if all copies are made on the same black and white printer and the same color printer.

The server will decide to print the entire print job on a color printer if Cc<Cs and to split the print job into two sub-jobs if Cc>Cs. Mathematically, this is equivalent to:

$$\{ \begin{matrix}If B * N > E / ( Pc - Pb ) \text{:} & Split the job into two sub \text{-} jobs ; \\ If B * N < E / ( Pc - Pb ) \text{:} & Print the entire job on a color printer .\end{matrix}$$

Since the value E/(Pc−Pb) is a constant, the determination of whether to split the job depends on the number of black and white pages in the document (B) and the number of copies to be made (N).

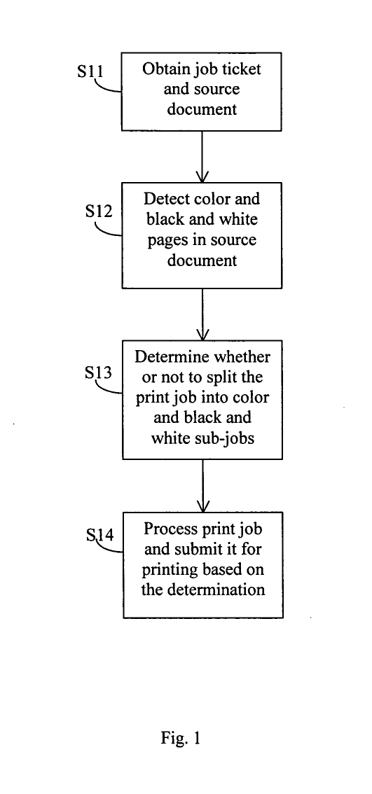

FIG. 1 illustrates a method implemented in a server for managing print jobs and printers according to an embodiment of the present invention. When a job ticket and the associated source document are received from a customer or otherwise obtained by the server (step S11), the server analyzes the source document to detect the color pages and black and white pages within the document (step S12). Typically, a document contains metadata that indicates the nature of its contents, including whether a particular page or object contains color or only black and white data. The server uses this metadata to detect which pages in the document are color and which pages are black and white and count the number of each type of pages. Alternatively, if the pages in the document are to be re-arranged when printed, e.g., when double-sided printing (two pages printed on two sides of each sheet of paper, also referred to as duplex) or two-on-one or multiple-on-one printing (two or more pages are reduced in size and printed on one page of paper, also referred to as N-up) is desired, then the server will analyze the document to determine which printed sheet (as opposed to page in the document) is color or black and white. The server then determines whether to split the print job into a color and a black and white sub-job, or to print the entire job on a color printer (step S13). Of course, if the document only contains black and white pages, the server will decide to print the entire job on a black and white printer. The determination in step S13 is based on a cost calculation described earlier, or some other appropriate cost evaluation formula. The server then processes the print job and submits it for printing by the appropriate printer or printers based on the determination (step S14). For example, if the server has determined that the job is to be split into two sub-jobs, the server will process the job ticket to generate two sub-job tickets, one for a color printer and one for a black and white printer, and separate the color and black and white pages in the source document to generate two corresponding documents to be sent to the two printers. Exemplary methods of splitting a job ticket are described in more detail in the above-mentioned co-pending patent application entitled “Method for Printing Mixed Color and Black and White Documents”. If, on the other hand, the server has determined that the entire job is to be printed on one printer, no additional processing of the source document is necessary before submitting it to a printer. Of course, if multiple copies (especially a large number of copies) are to be made, the job (whether split or not) can be printed on multiple printers simultaneously.

In the above example, the determination in step S13 is based on a cost calculation that compares the cost of splitting the print job versus not splitting the job. Alternatively, or in addition to cost considerations, the server may consider other factors in determining whether or not to split a print job. The factors may include the availability of different types of printers, the urgency of the job, etc. For example, if an urgent print job includes both color pages and black and white pages, but all of the black and white printers in the print shop are unavailable at the time, then the server may decide to print the entire document on a color printer even though it will be more costly. Alternatively, the cost consideration and the completion time consideration may be combined in making a decision.

Another example where it may be desirable to print certain black and white pages with a color printer is the booklet mode, where both sides of the paper are printed and the printout is bound into a booklet. If a black and white page faces a color page in an open booklet, and if the black and white page is printed with a black and white printer and the color page is printed with a color printer, then the two pages may have visibly different appearance when seen next to each other. This is because a page printed with a black and white printer will have a different appearance from a page printed with a color printer because of toner difference, machine condition difference, etc. Thus, it may be desirable to print such a black and white page on a color printer to reduce the undesirable difference in appearance of the two facing pages, even though it will increase the printing cost.

In light of these different considerations, different priority modes may be pre-defined in the server, such as a cost priority mode, a completion-time priority mode, etc. so that the server may be selectively set in one of such modes by the operator through a priority command.

In the above descriptions, the term “black and white” includes gray scales if the black and white printers are capable of printing gray scale images (e.g. using half-toning or some other suitable method). If, on the other hand, the black and white printers available at a print shop are not capable of printing gray scales, and gray scales must be printed on a color printer, then the server will treat a page with gray scale images as a color page. Further, the methods may be applied in a print shop system that includes monochromic printers, i.e., printers that can print only one color (e.g. only red) or shades of one color. In such a situation, the determination to be made will be whether a source document that contains both full color pages (i.e. pages having more than one color) and monochromic pages should be printed entirely by a color printer or be split into two sub-jobs, one for a monochromic printer and one for a color printer. (Note that a black and white printer is a monochromic printer.) As another alternative, a print shop may have black and white printers, full color printers, and monochromic printers for a non-black color, and the server will determine whether to print a mixed source document on one, two or more of these printers. More generally, embodiments of the present invention are directed to methods for managing a print shop system that has two or more categories of printers each having a different color capability such as black and white, color or the other examples described above, where the server determines whether to print a document to one, two or more categories of printers based on a cost consideration and/or other considerations. When the server analyzes the source document to determine the color characteristics of its pages, it uses definitions of color categories, e.g., black and white, color, etc., that correspond to the color capabilities of the categories of printers. The definitions of color categories may be programmed into the server software by the operator to suit the need of the particular shop.

While the embodiments have been described as being applied in a print shop environment, the invention is not limited to any physical setting of a shop, and can be applied to a print shop system having a distributed setting where printers at different locations are connected to a server.

It will be apparent to those skilled in the art that various modification and variations can be made in the print shop management method and apparatus of the present invention without departing from the spirit or scope of the invention. Thus, it is intended that the present invention cover modifications and variations that come within the scope of the appended claims and their equivalents.

What is claimed is:

1. A method for managing a print shop system, the print shop system including a plurality of categories of printers having different color capabilities, the method being implemented on a server connected to the printers, the method comprising:
(a) obtaining a print request and a source document to be printed;
(b) analyzing the source document according to definitions of a plurality of color categories that correspond to the color capabilities of the categories of printers to determine which color category each page of the document belongs;
(c) determining whether to print the source document on a single category of printers or to print the source document on two or more categories of printers based on the analysis of step (b) and pre-defined criteria; and
(d) submitting print requests to one or more categories of printers based on the determination of step (c).

2. The method of claim 1, wherein the pre-defined criteria include a comparison between a cost of printing the source document on a single category of printers and a cost of printing the source document on two or more categories of printers.

3. The method of claim 1, wherein the print shop system includes a category of black and white printers and a category of color printers,
wherein step (b) includes detecting at least a number of black and white pages in the source document, and
wherein the pre-defined criteria in step (c) include determining whether the number of black and white pages in the document multiplied by a number of copies of the document to be made is greater than or less than a cost of performing split printing divided by a per page cost difference between printing a color page and printing a black and white page.

4. The method of claim 1, wherein pre-defined criteria include a consideration based on the availability of the different categories of printers and a requested completion time for the printing.

5. The method of claim 1, further comprising:
(e) receiving a priority command from an operator, the priority command being a cost priority command or a completion-time priority command;
wherein in step (c), the pre-defined criteria is selected, based on the received priority command, between a first criteria relating to a cost of printing the document and a second criteria relating to an estimated time of completing printing the document.

6. A computer program product comprising a computer usable medium having a computer readable code embodied therein for controlling a data processing apparatus, the computer readable program code configured to cause the data processing apparatus to execute a process for managing a print shop system, the print shop system including a plurality of categories of printers having different color capabilities and connected to a server, the process comprising the steps of:
(a) obtaining a print request and a source document to be printed;
(b) analyzing the source document according to definitions of a plurality of color categories that correspond to the color capabilities of the categories of printers to determine which color category each page of the document belongs;
(c) determining whether to print the source document on a single category of printers or to print the source document on two or more categories of printers based on the analysis of step (b) and pre-defined criteria; and
(d) submitting print requests to one or more categories of printers based on the determination of step (c).

7. The computer program product of claim 6, wherein the pre-defined criteria include a comparison between a cost of printing the source document on a single category of printers and a cost of printing the source document on two or more categories of printers.

8. The computer program product of claim 6, wherein the print shop system includes a category of black and white printers and a category of color printers,
wherein step (b) includes detecting at least a number of black and white pages in the source document, and
wherein the pre-defined criteria in step (c) include determining whether the number of black and white pages in the document multiplied by a number of copies of the document to be made is greater than or less than a cost of performing split printing divided by a per page cost difference between printing a color page and printing a black and white page.

9. The computer program product of claim 6, wherein pre-defined criteria include a consideration based on the availability of the different categories of printers and a requested completion time for the printing.

10. The computer program product of claim 6, wherein the process further comprises:
(e) receiving a priority command from an operator, the priority command being a cost priority command or a completion-time priority command;
wherein in step (c), the pre-defined criteria is selected, based on the received priority command, between a first criteria relating to a cost of printing the document and a second criteria relating to an estimated time of completing printing the document.
